(19) United States
(12) Patent Application Publication
(10) Pub. No.: US 2012/0235188 A1
(43) Pub. Date: Sep. 20, 2012

(54) Method and Apparatus for a Flat Top Light Source

(75) Inventors: Chin Ewe Phang, Penang (MY); Meng Ee Lee, Penang (MY); Eng Chuan Ong, Penang (MY)

(73) Assignee: AVAGO TECHNOLOGIES ECBU IP (SINGAPORE) PTE. LTD., SINGAPORE (SG)

(21) Appl. No.: 13/048,136

(22) Filed: Mar. 15, 2011

(51) Int. Cl. H01L 33/50

(52) U.S. Cl. 257/98; 257/E33.061

(57) ABSTRACT

A light-emitting device and method for manufacturing the device are disclosed. In one embodiment, the light-emitting device comprises a flat substrate and an encapsulation layer formed above the flat substrate. The top portion of the encapsulation layer is flat and the encapsulation layer is divided into a high density layer and a low density layer. The high density layer is formed from a wavelength-converting material precipitated on one side of the encapsulation layer. In the low density layer, the wavelength-converting material exists in particle form suspended within the encapsulation layer.

### BACKGROUND

Light-emitting diodes (referred to hereinafter as LEDs) represent one of the most popular light-emitting devices today. Due to the small form factor and low power consumption, LEDs are widely used in electronic mobile devices as indicator lights, light sources for Liquid Crystal Displays or LCDs, as well as flashes in camera phones, digital cameras and video recording to devices. Compared to Xenon flashes used in most cameras, LEDs are superior in terms of size and power consumption. For example, an LED in a flash application may have a thickness of 0.6 mm compared to Xenon flashes that has a thickness of 1.3 mm. The small form factor makes LEDs suitable in mobile camera devices or mobile phones with a camera feature that may have an overall thickness less than 5 mm. In addition, unlike Xenon flashes, LEDs do not require charging time before use.

Generally, most light-emitting devices are not made for a single application, but for multiple applications. The light-emitting devices used in flashes are usually high power and high output light sources. Therefore, other suitable applications for light-emitting devices used in flashes are high power applications, such as indicator lights, light sources used in lighting fixtures or light sources used in infotainment displays. Electronic infotainment display systems are usually large-scale display systems, which may be found in stadiums, discotheques, electronic traffic sign displays and infotainment billboards along streets and roadways. Electronic infotainment displays may be configured to display text, graphics, images or videos containing information or entertainment contents.

Most of the flashes used today are white light sources. However, light produced by light source dies in most LEDs are generally a narrow banded light having a peak wavelength ranging from ultra violet to green wavelength. The output of the light source die is then typically converted to a broad spectrum white light by means of a wavelength-converting material. One example of a wavelength-converting material is phosphor. The wavelength-converting material may absorb a portion of light, resulting in light loss. The light lost is usually not substantial, but may be significant if the wavelength-converting material is thick.

There are several design considerations in designing a light-emitting device, such as viewing angle, color point, heat dissipation, power consumption and form factor, to name a few. Generally light-emitting devices are designed giving priority to design considerations in a primary application. For example, the light-emitting devices targeted for a flash application in camera devices tend to be small in form factor and have a high light output. However, light-emitting devices can often be used outside the targeted, primary application.

### BRIEF DESCRIPTION OF THE DRAWINGS

Illustrative embodiments by way of examples, not by way of limitation, are illustrated in the drawings. Throughout the description and drawings, similar reference numbers may be used to identify similar elements.

FIG. 1 illustrates a cross-sectional view of a light-emitting device having sidewalls;

FIG. 2 illustrates a cross-sectional view of a light-emitting device without sidewalls manufactured using a transfer mold process;

FIG. 3 illustrates a cross-sectional view of a light-emitting device having a layer of wavelength-converting material coated on the light source die;

FIG. 4A illustrates a perspective view of a light-emitting device manufactured using a group casting method;

FIG. 4B illustrates a cross-sectional view of the light-emitting device shown in FIG. 4A taken along line 4-4;

FIG. 4C illustrates density of the wavelength-converting material in the encapsulation layer of the light-emitting device shown in FIGS. 4A and 4B;

FIG. 5A illustrates a perspective view of a light-emitting device having a flip chip die manufactured using a group casting method;

FIG. 5B illustrates a cross-sectional view of the light-emitting device shown in FIG. 5A taken along line 5-5;

FIG. 6 illustrates a cross-sectional view of a light-emitting device having connector pads located away from the side;

FIGS. 7A-7H illustrate how light-emitting devices are fabricated using a group casting method; and

FIG. 8 illustrates a flow chart representing a method for manufacturing a light-emitting device.

### DETAILED DESCRIPTION

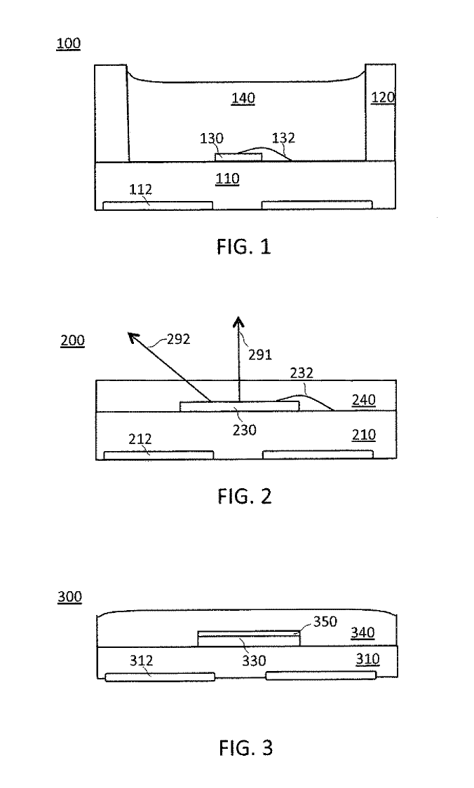

FIG. 1 illustrates a cross-sectional view of a light-emitting device 100. The light-emitting device 100 comprises a substrate 110, connector pads 112, a body 120, a light source die 130, a wire bond 132 bonding the die 130 to the substrate 110, and an encapsulant 140. The encapsulant 140 encapsulates the light source die 130 and the wire bond 132. The body 120 defines side walls configured to direct light from the light-emitting device. Due to the intermolecular forces that holds the liquid together when the encapsulant 140 is in a liquid form during the manufacturing process, the top surface of the encapsulant 140 may not be completely flat. The body 120 may be molded. While the body 120 may increase the reliability performance, the body 120 occupies substantial space that may be otherwise reduced.

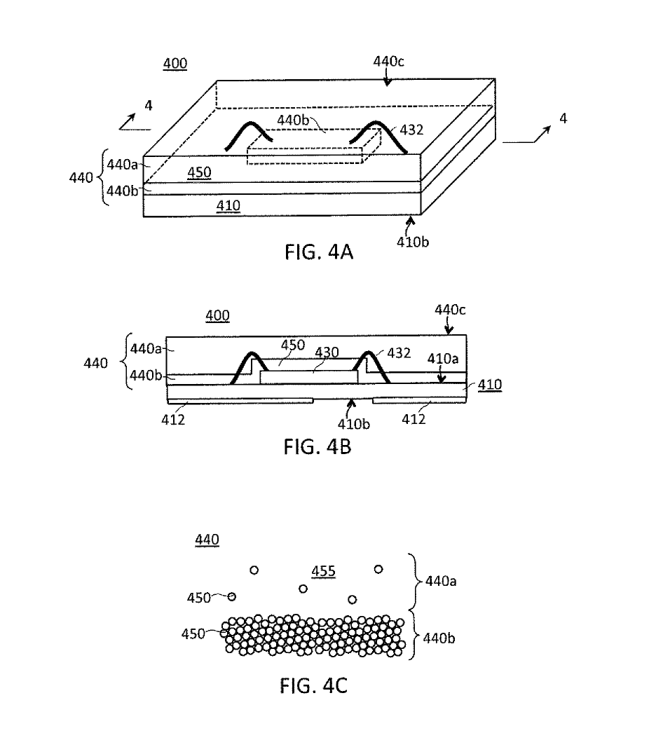

FIG. 2 illustrates a light-emitting device 200 without sidewalls manufactured by means of a transfer mold process. The light-emitting device 200 comprises a substrate 210, connector pads 212, a light source die 230, a wire bond 232 bonding the die 230 to the substrate 210, and an encapsulation layer 240. The encapsulation layer 240 may be formed from a B-stage encapsulant mixed with a wavelength-converting material (not shown). A B-stage encapsulant is an intermediate stage in the reaction of certain thermosetting resins, in which the material softens when heated, and swells when in contact with certain liquids, but the material may not entirely fuse or dissolve. The wavelength-converting material (not shown) is distributed substantially evenly in the encapsulation layer 240. The wavelength-converting-material (not shown) may cause light loss as a portion of light may be absorbed. The encapsulation layer 240 may be required to have a certain thickness, in order to enable the functionality of the encapsulation layer 240 to protect the light source die 230 from moisture and vibration. However, the light loss may become significant, as the thickness of encapsulation layer 240 is increased.

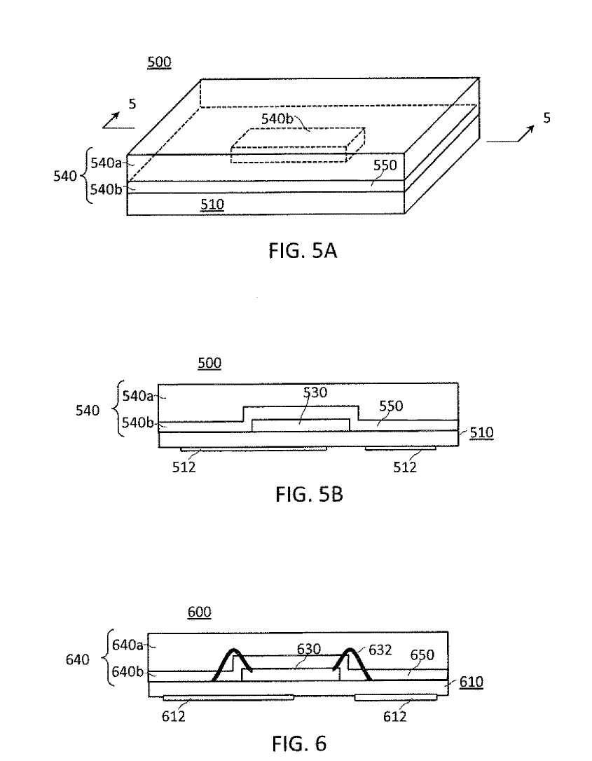

An effective way to reduce light loss is by using a thin layer of light-converting material 350, as shown in FIG. 3, which illustrates a cross-sectional view of a light-emitting device 300 comprising a substrate 310, connector pads 312, a light source die 330, a thin layer of wavelength-converting material 350 coated on the light source die 330, and an encapsulation layer 340. The encapsulation layer 340 encapsulates the light source die 330 and the thin layer of wavelength-converting material 350. The wavelength-converting material 350 may be attached to an upper relatively flat surface of the light source die 330. Therefore, the light source die 330 is usually a flip chip die. The encapsulation layer 340 may be formed using a spin molding or a spinning process. The encapsulation layer 340 may not be flat. In addition, the spin molding process may not be cost effective.

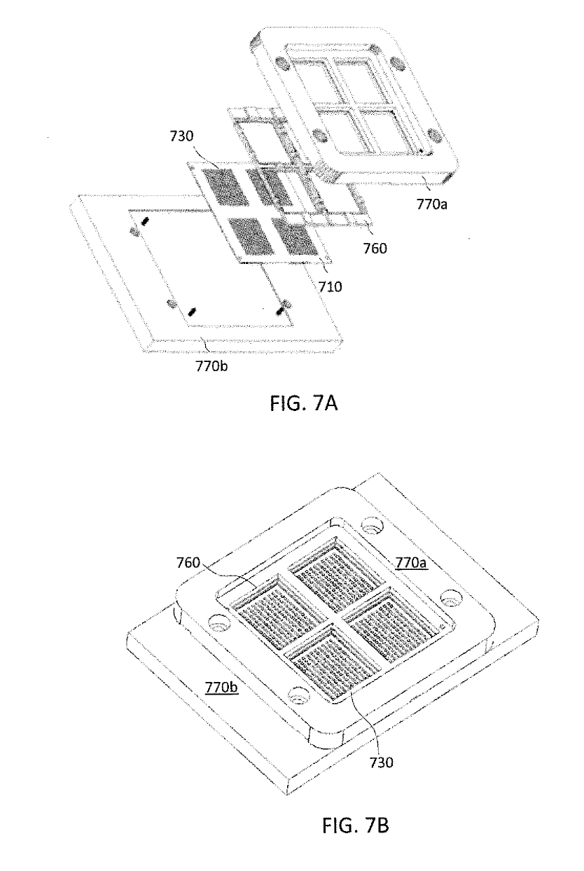

One cost effective method for manufacturing a miniature light-emitting device with minimum light loss and a flat top surface is to use a group casting method. FIG. 4A illustrates a perspective view of light-emitting device 400. FIG. 4B shows a cross-sectional view of the light-emitting device 400 along line 4-4, shown in FIG. 4A. Referring to FIGS. 4A and 4B, the light-emitting device 400 comprises a substrate 410, connector pads 412, a light source die 430, a wire bond 432 connecting the die 430 to the substrate 410, an encapsulation layer 440 encapsulating the light source die 430 and the wire bond 432, and a wavelength-converting material 450.

The substrate 410 is substantially flat with an upper surface 410a and a bottom surface 410b. The substrate 410 may be a printed circuit board (referred herein after as PCB). The bottom surface 410b may further comprise connector pads 412. The connector pads 412 may extend from one side of the substrate 410, as shown in FIG. 4B. The connector pads 412 may be connected to an external power source (not shown) for providing power to the light-emitting device 400. The connector pad 412 may be connected to a die attach pad (not shown) through one or a plurality of conducting material(s), typically referred to as a “via” (not shown), extending from the bottom surface 410b to the top surface 410a of the substrate. The “vias”, connector pads 412 and die attach pads may function as heat dissipation vehicles, dissipating heat generated by the light source die 430 to the surroundings.

The light source die 430 is configurable to emit light. For example, the light source die 430 may be a semiconductor based LED die, such as a Gallium Nitride (GaN) die, Indium. Gallium Nitride (InGaN), or any other similar die configurable to produce light having a peak wavelength ranging between 300 nm and 520 nm. The light emitted by the light source die 430 is then converted into broad-spectrum white light by the wavelength-converting material 450. The wavelength-converting material 450 may be yellow phosphor, red phosphor, green phosphor, orange phosphor or any other material capable of converting a narrow banded peak-wavelength light into broad spectrum white light.

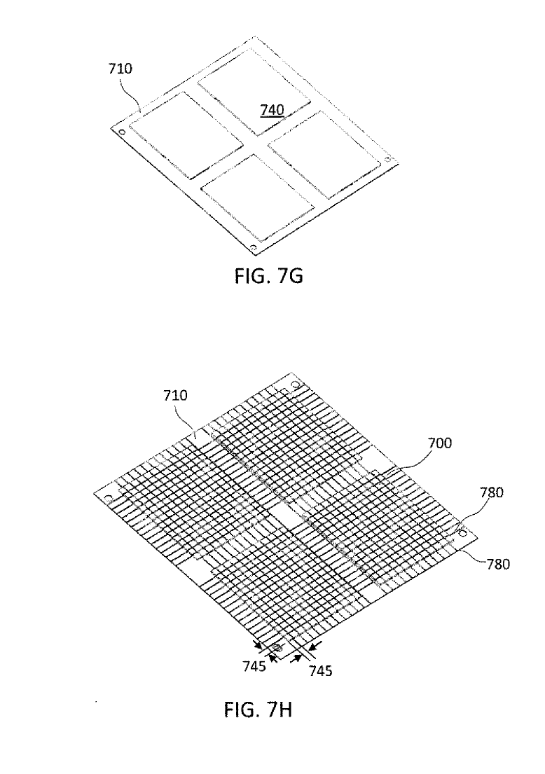

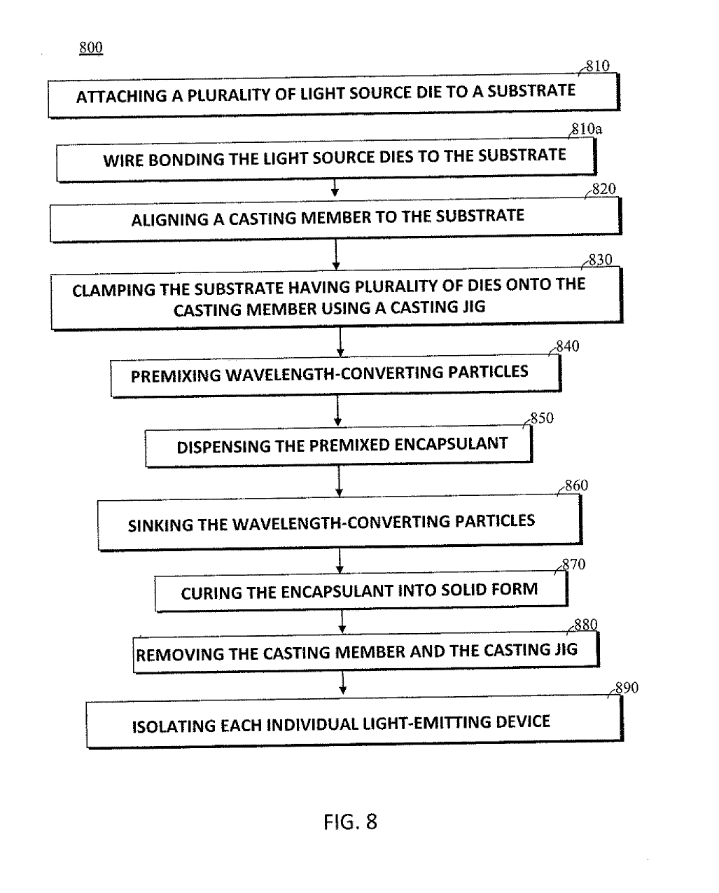

Due to manufacturing methods, the encapsulation layer 440 may further comprise a low density layer 440a and a high density layer 440b, which is further illustrated in FIG. 4C. The encapsulation layer 440 may formed by mixing wavelength-converting material 450 into an encapsulant 455 in liquid form during the manufacturing process, and subsequently the mixture is allow to precipitate. The precipitation process may occur simultaneously during the curing process when the liquid encapsulant is cured into solid form. The encapsulant 455 may be epoxy, silicon or any other similar material. The high density layer 440b is formed by a layer of precipitated wavelength-converting material 450, as shown in FIG. 4C. The low density layer 440a, on the other hand, is not completely void of wavelength-converting material 450, but having very low density of the wavelength-converting material 450 suspended within the encapsulant 455 in particle form. The details of the manufacturing process are further discussed with reference to FIGS. 7A-7H and FIG. 8.

Unlike the light-emitting device 200, shown in FIG. 2, the encapsulant 455 used during the mixing process is in A-stage. A-stage is an early stage in the reaction of certain thermosetting resins in which the material is fusible and still soluble in certain liquids. As the encapsulant 455 is in A-stage, the wavelength-converting material 450 can be precipitated on one side. This process defines the encapsulation layer 440 into the low density layer 440a and the high density layer 440b. As the wavelength-converting material 450 is a thin layer, light loss due to the wavelength-converting material 450 is minimal. In the embodiment shown in FIG. 4B, the high density layer is in direct contact with the top surface 410a of the substrate 410. However, in other embodiments, the arrangement may be reversed such that the low density layer 440a is in direct contact with the top surface 410a of the substrate 410. The arrangement of low density layer 440a and the high density layer 440b depends on the orientation of the substrate 410 during manufacturing process as discussed further with reference to FIG. 8.

As shown in the embodiment in FIG. 4B, the wire bonds 432 are encapsulated in the encapsulation layer 440. However, a portion of the wire bond 432 is encapsulated within the high density layer 440b, while the remaining portion of the wire bond 432 is encapsulated within the low density layer 440a. In yet another embodiment, the entire wire bond 432 may be enclosed within only one of either the high density layer 440b or the low density layer 440a.

As shown in FIG. 4A, the light-emitting device 400 defines a rectangular shape. The substrate 410 and the encapsulation layer 440 are both rectangular shapes overlapping each other completely. In the embodiment shown in FIG. 4A, each of the substrate 410 and the encapsulation layer 440 have four sides respectively, which are aligned to each other, respectively. In yet another embodiment that the light-emitting device 400 may define a flat disc shape, with each of the substrate 410 and the encapsulation layer 440 having similar discs that are aligned with each other.

The top surface 440c of the encapsulation layer 440 defines a substantially flat surface without any meniscus. A meniscus is a curve in the upper surface of a standing liquid, produced in response to the surface of the container of the liquid such as the mold used to form the encapsulation layer 440. A meniscus can be either convex or concave. Due to the group casting method, discussed more fully with reference to FIG. 8 below, meniscus can be eliminated by means of a dummy area 745, as shown in FIG. 7H and discussed with reference to FIG. 8 below. This is one of the advantages of the light-emitting device 400 compared to the light-emitting device 300 shown in FIG. 3 in which the encapsulant 340 is formed individually.

Generally, both the low density layer 440a and the high density layer 440b may be substantially flat and planarly parallel to the substrate 410. However, in the embodiment shown in FIGS. 4A-48, the high density layer 440b may not be completely flat. A portion of the high density layer 440b may be enclosing and thus defining the shape of the light source die 430. In one embodiment, the substrate 410 has a thickness of approximately 0.1 mm, the high density layer 440b has a thickness of approximately 0.25 mm and the low density layer is approximately 0.35 mm. The light source die 430 has a thickness of approximately 0.15 mm. The overall thickness of the light-emitting device 400 is approximately 0.6 mm. The dimension of the light-emitting device 400 is approximately 2.0 mm×2.0 mm×0.6 mm. Comparing the light-emitting device 400 and the light-emitting device 100 shown in FIG. 1, the light-emitting device 400 without the sidewalls 200 (See FIG. 1) can be made relatively smaller. In addition, the form factor and small size of the light-emitting device 400 is suitable for many applications, for example, flash light in mobile devices such as camera phones, compact cameras and any other camera devices, among other things.

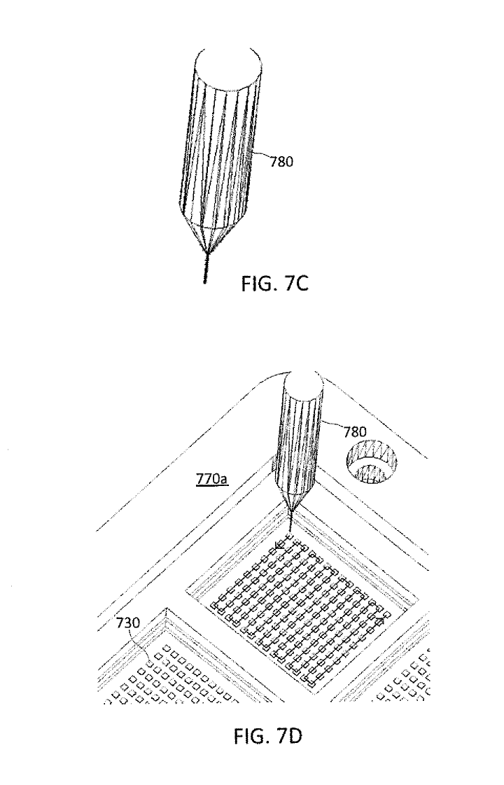

FIG. 5A illustrates a perspective view of a light-emitting device 500 having a flip chip die manufactured using a group casting method. FIG. 5B illustrates a cross-sectional view of the light-emitting device 500, shown in FIG. 5A taken along line 5-5. The light-emitting device 500 is substantially similar to the light-emitting device 400, but differs at least in the fact that the light-emitting device 500 does not have any wire bonds 432 as in FIG. 4A. The light-emitting device 500 comprises a substrate 510, connector pads 512, a light source die 530, an encapsulation layer 540 encapsulating the light source die 530, and wavelength-converting material 550. Without the wire bond 432 (in FIG. 4A), the light source die 530 is connected to the substrate 510 through solder balls (not shown), which may be used in flip chip die manufacturing. The encapsulation layer 540 of the light-emitting device 500 further comprises a high density layer 540b and a low density layer 540a, as discussed above in FIGS. 4A-4C.

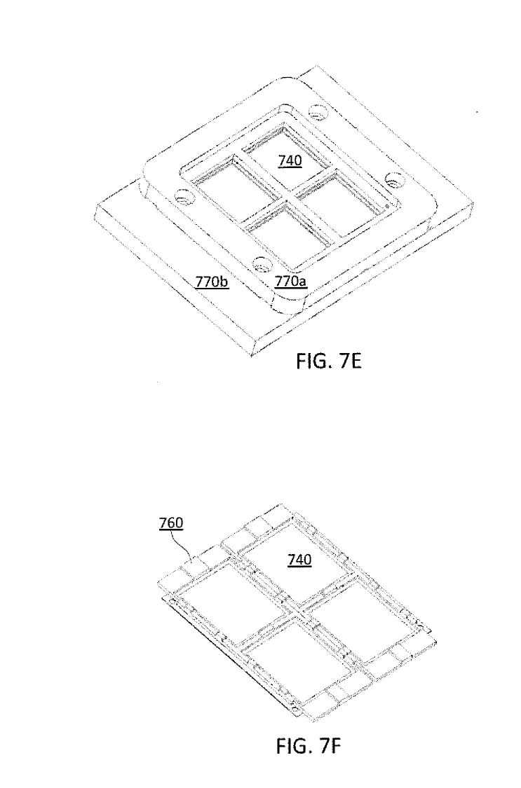

FIG. 6 illustrates a light-emitting device 600, which comprises a substrate 610, connector pads 612, a light source die 630, a wire bond 632 connecting the die 630 to the substrate 610, an encapsulation layer 640 encapsulating the light source die 630 and the wire bond 632, and a wavelength-converting material 650. The encapsulation layer 640 further comprises a high density layer 640b and a low density layer 640a. The light-emitting device 600 is substantially similar to the light-emitting device 400 shown in FIG. 4B, but differs at least in the location of the connector pads 612. The connector pads 612 shown in FIG. 6 are not located at the side of the light-emitting device 600, but are located at a distance from each side of the light-emitting device 600. During some sawing processes, any metal portions, such as the connector pads 612 may be ripped off of the device during the sawing process if the metal portion is within the saw line 780 (See FIG. 7H). Thus, the separation of the metal connector pads from the sides of the device ensures the formation of the connector pads 612 without being ripped off during any sawing processes of manufacturing.

FIGS. 7A-7H illustrate how the light-emitting devices 700 are fabricated using a group casting method as discussed with reference to the flow chart of FIG. 8. Referring to FIGS. 7A-7H and FIG. 8, the method for fabricating light-emitting device 700 (shown in FIG. 7h) starts with step 810 in which a plurality of light source dies 730 are attached on a substrate 710, as shown in FIG. 7A. In the embodiment shown in FIG. 7A, the substrate 710 is a PCB having four groups of light source dies 730 (See also FIG. 7B), attached to a top surface of the substrate 710. Each group may comprise 150 light source dies 730. Alternative numbers and arrangements may be possible, depending on design and manufacturing requirements. For non-flip chip type of light source dies 730, optional step 810a may occur, in which wire bonding the light source dies 730 to the substrate 710 may be required. Next, the method proceeds to step 820 in which a casting member 760, having at least one cavity is aligned to the substrate 710, such that the light source dies 730 are enclosed within the cavity. In the embodiment shown in FIG. 7A, the casting member 760 is a casting rubber member defining four cavities configured to enclose each group of the light source dies 730. Other arrangements may be possible, including a casting member of other materials. In step 830, the casting member 760 and the substrate 710 are clamped together, using a casting jig 770a-770b, to fix the position of the casting member 760 relative to the substrate 710 as shown in FIG. 7B.

In step 840, which may be done concurrently to steps 810-830, an encapsulant having wavelength-converting material therein may be premixed. Step 840 can also be done before or after steps 810-830. The encapsulant is in A-stage that is a liquid form. The premixed encapsulant may be placed in a dispensing apparatus 780, as shown in FIG. 7C. Generally, the encapsulant needs to be used within a predetermined time period after preparation. Therefore, although the premixing of encapsulant may be done concurrently or prior to steps 810 to 830, usually step 840 is carried out after the die attach and wire bonding are done. The encapsulant may be silicon, epoxy or any other similar material.

The method then proceeds to step 850, in which the premixed encapsulant is dispensed into or over the cavities. In the embodiment shown in FIG. 7D, the dispensing is done in a zip-zag manner. However, other dispensing patterns may be used. Next, in step 860, the wavelength-converting material is then allowed to sink or settle, such that a low density layer and a high density layer are formed. In the low density layer, the wavelength-converting material (shown in FIG. 4C) suspends within the encapsulant 740 in particle form. On the contrary, the high density layer comprises of a layer of precipitated wavelength-converting material. In the embodiment shown in FIGS. 7A-7H, the sinking or settling process is done having the top surface of the substrate 710 facing upwards. Therefore, the high density layer is formed in direct contact with the top surface of the substrate. If the sinking process is done in an opposite manner in which the top surface of the substrate 710 faces downwards, the low density layer will form in direct contact with the top surface of the substrate 710. The sinking process may be done under a condition such as the casting jig 770a-770b is rotated to ensure that the thickness of the encapsulation layer is substantially consistent. Next, the method proceeds to step 870 in which the encapsulant is cured into a solid form. Step 860 and step 870 may be done substantially simultaneously. Step 860 may also comprise other details, such as degasing the encapsulation layer. In yet another embodiment, the step 870 of curing the encapsulation layer may be done in a temperature under 150 degrees Celsius for 4 hours, which is done after step 860.

Next, the process proceeds to step 880, in which the casting member 760 and the casing jig 770a-770b are removed, as shown in FIGS. 7F-7G. Finally, the method proceeds to step 890, in which each individual light-emitting is isolated, for example by means of sawing. In the embodiment shown in FIG. 7H, the common substrate 710, having a plurality of light source dies 730 being encapsulated within a layer of encapsulation layer may be sawed. This step may also be accomplished by means of chemical or laser etching, or other known separation means. Generally, the meniscus or curvature portions are formed at the outer perimeter of the encapsulation layer, because this is where the liquid encapsulant touches the casting member 760. An area at the outer perimeter of the encapsulation layer may be selected to define a dummy area 745. Dummy area 745 is an area where the substrate 710 is without attached light source dies 730 or circuits but being enclosed by the encapsulation layer. The size of the dummy area 745 is selected such that meniscus or curvature portions are formed only within the dummy area 745. The dummy area 745 can be easily removed by sawing or other separation means. Compared to the light-emitting device 200 shown in FIG. 2 manufactured using a transfer mold method, the elimination of the dummy area 745 is cost effective. Casting the light-emitting devices 700 in groups reduce the dummy area 745 needed per unit of devices.

FIG. 7H shows saw or separation lines 780 dividing the substrate 710 into columns and rows to yield a rectangular shape light-emitting device 700. As the side of the light-emitting device is produced through sawing, the size and shape of the encapsulation layer and the substrate 710 are substantially similar. One cost effective shape for the light-emitting device 700 is rectangular shape as more devices can be fit per unit area. However, for any other customization or any needs to adapt the form factor into other shapes, the method illustrated in FIG. 8 is applicable. For example, for a disc shape device, the isolation of individual devices may be done through laser cutting, V-cutting, stamping or any other similar process instead of the sawing process illustrated in the example given above.

Although specific embodiments of the invention have been described and illustrated herein above, the invention should not be limited to any specific forms or arrangements of parts so described and illustrated. For example, the light source die described above may be an LED die or some other future light source die. Likewise, although a light-emitting device with a single die was discussed, the light-emitting device may contain any number of dies, as known or later developed without departing from the spirit of the invention. The scope of the invention is to be defined by the claims appended hereto and their equivalents. Similarly, manufacturing embodiments and the steps thereof may be altered, combined, reordered, or other such modification as is known in the art to produce the results illustrated.

What is claimed is:

1. A light-emitting device, comprising:
a substrate, the substrate having top and bottom surfaces;
a light source die attached to the top surface;
an encapsulation layer encapsulating the light source die and the top surface; and
a wavelength-converting material formed within the encapsulation layer;
wherein the encapsulation layer further comprises:
a low density layer substantially planarly parallel to the top surface of the substrate, wherein the low density layer having the wavelength-converting material suspending within the low density layer in particles form; and
a high density layer substantially planarly parallel to the top surface of the substrate, wherein the high density layer is formed by the wavelength-converting material precipitated on one side of the encapsulation layer.

2. The light-emitting device of claim 1, wherein the substrate and the encapsulation layer further comprise side surfaces that have substantially the same perimeter with side walls that are substantially above and below each other.

3. The light-emitting device of claim 1, wherein the high density layer is in direct contact with the top surface of the substrate.

4. The light-emitting device of claim 1, further comprising a wire bond encapsulated within the encapsulation layer.

5. The light-emitting device of claim 4, wherein the wire bond is encapsulated within the high density layer.

6. The light-emitting device of claim 4, wherein a portion of the wire bond is encapsulated within the low density layer and another portion of the wire bond is encapsulated within the high density layer.

7. The light-emitting device of claim 1, wherein the encapsulation layer further comprises a top flat surface.

8. The light-emitting device of claim 1, wherein the light source die is a flip chip die.

9. The light-emitting device of claim 1, wherein the light-emitting device defines a rectangular shape

10. The light-emitting device of claim 1, wherein the bottom surface of the substrate comprises a connector pad extending from at least one side of the bottom surface.

11. The light-emitting device of claim 1, wherein the light-emitting device forms a portion of a camera device.

12. A method for making a plurality of light-emitting devices, the method comprising:
attaching a plurality of light source dies on a substrate;
aligning a casting member having at least one cavity to the substrate such that the plurality of light source dies are enclosed within the at least one cavity;
fixing the position of the casting member relative to the substrate using a casting jig;
premixing an encapsulant in liquid form having a wavelength-converting material;
dispensing the encapsulant into the at least one cavity;
allowing the wavelength-converting material to precipitate and form thereon a high density layer, and a low density layer, wherein the high density layer comprises precipitated wavelength-converting material and the low density layer comprises the wavelength-converting material suspending within the encapsulant in particle form;
curing the encapsulant layer into solid form;
removing the casting member and the casting jig; and
isolating each individual light-emitting device.

13. The method of claim 12, wherein the steps of allowing the wavelength-converting material to precipitate and curing the encapsulant layer are done simultaneously.

14. The method of claim 12, further comprising removing any curvature portion of the encapsulant layer to obtain a substantially flat encapsulant layer.

15. The method of claim 12, wherein the method further comprises rotating the casting jig during the step of allowing the wavelength-converting material to precipitate.

16. The method of claim 12, wherein the step of isolating each individual light source device comprises sawing the substrate.

17. The method of claim 12, wherein the casting member comprises a plurality of cavities and the light source dies in each cavity are cast simultaneously.

18. The method of claim 12, further comprising wire-bonding the light source dies to the substrate.

19. The method of claim 18, wherein the high density layer encapsulates a portion of wire bond foamed during the wire-bonding process.

20. A flash used in mobile devices, comprising:
a flat substrate, the substrate having top and bottom surfaces;
a light source die attached on the top surface;
an encapsulation layer encapsulating the light source die and the top surface, wherein the encapsulation layer further comprises:
a layer of low density wavelength-converting material, the wavelength-converting material being in particle form suspended within the encapsulation layer; and
a layer of high density precipitated wavelength-converting material substantially planarly parallel to the top surface.
